(19) United States
(12) Patent Application Publication
(10) Pub. No.: US 2010/0266765 A1
(43) Pub. Date: Oct. 21, 2010

(54) METHOD AND APPARATUS FOR GROWING A THIN FILM ONTO A SUBSTRATE

(76) Inventors: Carl L. White, Gilbert, AZ (US); Eric J. Shero, Phoenix, AZ (US)

Correspondence Address: Knobbe, Martens, Olson & Bear LLP, 2040 Main Street, 14th Floor, Irvine, CA, 92614, US

(21) Appl. No.: 12/427,690

(22) Filed: Apr. 21, 2009

(51) Int. Cl. C23C 16/44; C23C 16/54

(52) U.S. Cl. 427/248.1; 118/715

(57) ABSTRACT

An apparatus and method of growing a thin film onto a substrate comprises placing a substrate in a reaction chamber and subjecting the substrate to surface reactions of a plurality of vapor-phase reactants according to the ALD method. Non-fully closing valves are placed into the reactant feed conduit and backsuction conduit of an ALD system. The non-fully closed valves are operated such that one valve is open and the other valve is closed during the purge or pulse cycle of the ALD process.

### BACKGROUND OF THE INVENTION

1. Field of the Invention

This application relates generally to processing films and, in particular, to systems and methods of growing a thin film onto a substrate.

2. Description of the Related Art

There are several vapor deposition methods for depositing thin films on the surface of substrates. These methods include vacuum evaporation deposition, Molecular Beam Epitaxy (MBE), different variants of Chemical Vapor Deposition (CVD) (including low-pressure and organometallic CVD and plasma-enhanced CVD), and Atomic Layer Epitaxy (ALE), which is more recently referred to as Atomic Layer Deposition (ALD).

ALD is a known process in the semiconductor industry for forming thin films of materials on substrates such as silicon wafers. ALD is a type of vapor deposition wherein a film is built up through self-saturating reactions performed in cycles. The thickness of the film is determined by the number of cycles performed. In an ALD process, gaseous precursors or reactants are supplied, alternatingly and repeatedly, to the substrate or wafer to form a thin film of material on the wafer. One reactant adsorbs in a self-limiting process on the wafer. A subsequent reactant pulse reacts with the adsorbed material to form a single molecular layer of the desired material. Decomposition may occur through reaction with an appropriately selected reagent, such as in a ligand exchange or a gettering reaction. In a typical ALD reaction, no more than a molecular monolayer forms per cycle. Thicker films are produced through repeated growth cycles until the target thickness is achieved.

In an ALD process, one or more substrates with at least one surface to be coated and reactants for forming a desired product are introduced into the reactor or deposition chamber. The one or more substrates are typically placed on a wafer support or susceptor. The wafer support is located inside a chamber defined within the reactor. The wafer is heated to a desired temperature above the condensation temperatures of the reactant gases and below the thermal decomposition temperatures of the reactant gases.

A characteristic feature of ALD is that each reactant is delivered to the substrate in a pulse until a saturated surface condition is reached. As noted above, one reactant typically adsorbs on the substrate surface and a second reactant subsequently reacts with the adsorbed species. As the growth rate is self-limiting, the rate of growth is proportional to the repetition rate of the reaction sequences, rather than to the temperature or flux of reactant as in CVD.

To obtain self-limiting growth, vapor phase reactants are kept separated by purge or other removal steps between sequential reactant pulses. Since growth of the desired material does not occur during the purge step, it can be advantageous to limit the duration of the purge step. A shorter duration purge step can increase the available time for adsorption and reaction of the reactants within the reactor, but because the reactants are often mutually reactive, mixing of the vapor phase reactants should be avoided to reduce the risk of CVD reactions destroying the self-limiting nature of the deposition. Even mixing on shared lines immediately upstream or downstream of the reaction chamber can contaminate the process through parasitic CVD and subsequent particulate generation.

### SUMMARY OF THE INVENTION

To prevent the vapor phase reactants from mixing, ALD reactors may include an “inert gas valving” or a “diffusion barrier” arrangement in a portion of a supply conduit to prevent flow of reactant from a reactant source to the reaction chamber during the purge step. Inert gas valving involves forming a gas phase, convective barrier of a gas flowing in the opposite direction to the normal reactant flow in the supply conduit. See T. Suntola, Handbook of Crystal Growth III, Thin Films and Epitaxy, Part B: Growth Mechanisms and Dynamics, ch. 14, Atomic Layer Epitaxy, edited by D. T. J. Hurle, Elsevier Science V. B. (1994), pp. 601-663. See especially, pp. 624-626. Although such prior art arrangements have been successful in preventing vapor phase reactants from mixing, there is still room for improvement.

For example, U.S. Pat. Nos. 6,783,590 and 7,018,478 describe a method of using non-fully closing valves in a conduit system along with a flow ratio sequencer to eliminate valves within a hot zone. However, using a non-fully closing valve within the flow regulator, or mass flow controller, of the reactant and/or inert gas can increase the amount of reactant consumed in the ALD process, thus increasing the costs to the ALD process user.

A need therefore exists for an improved gas valve arrangement and mode of operation which is easier to purge and more effectively separates gas reactant pulses.

Accordingly, one embodiment comprises an apparatus for growing a thin film onto a substrate according to the ALD method. The apparatus includes a reaction chamber in which the substrate is positioned and a reactant source in communication with the reaction chamber via a first conduit. A flow regulation system is configured to regulate the flow of vaporized reactant via the first conduit into said reaction chamber to cause the vaporized reactant to enter the reaction chamber in the form of repeated vapor-phase pulses that alternated with repeated vapor-phase pulses of at least one other reactant to react with the surface of the substrate at a reaction temperature to form a thin film on said substrate. The flow regulation system includes a source of inactive gas, which is in communication with the first conduit via a second conduit which is connected to the first conduit at a first connection point and a drain of gas, which is in communication with the first conduit via a third conduit which is connected to the first conduit at a second connection point upstream of the first connection point. A first non-fully closing valve is arranged upstream of the second connection point to provide flow in a closed position. A second non-fully closing valve is arranged downstream of the second connection point to provide flow in a closed position. A control system is operatively coupled to the first and second non-fully closing valves. The control system is configured to close the second non-fully closing valve when the first non-closing valve is opened and to open the second non-fully closing valve when the first non-fully closing valve is closed.

In another arrangement, a method of growing a thin film onto a substrate placed in a reaction chamber according to the ALD method comprises vaporizing a reactant from a reactant source maintained at a vaporizing temperature. The vaporized reactant is conducted to the reaction chamber via a first conduit. The reactant is fed into said reaction chamber though the first conduct in the form of vapor-phase pulses repeatedly and alternately with vapor-phase pulses of at least one other reactant. The vapor-phase reactant reacts with the surface of the substrate at a reaction temperature to form a thin film compound on said substrate. Inactive gas is fed into said first conduit via a second conduit, connected to the first conduit at a first connection point, during the time interval between the vapor-phase pulses of the reactant so as to form a gas phase barrier against the flow of the vaporized reactant from the reactant source via the first conduit into the reaction chamber. The inactive gas is withdrawn from said first conduit via a third conduit connected to the first conduit and through a non-fully closing valve in an open position in the third conduit. The non-fully closing valve in the third conduit is placed into a reduced flow position when feeding the reactant into said chamber through the first conduit.

In another arrangement, a method of growing a thin film onto a substrate placed in a reaction chamber according to the ALD method comprises vaporizing a reactant from a reactant source maintained at a vaporizing temperature. The vaporized reactant is transferred to the reaction chamber via a first conduit. The reactant is fed into said reaction chamber though the first conduct in the form of vapor-phase pulses repeatedly and alternately with vapor-phase pulses of at least one other reactant. The vapor-phase reactant reacts with the surface of the substrate at a reaction temperature to form a thin film compound on said substrate. The inactive gas is fed into said first conduit via a second conduit, connected to the first conduit at a first connection point, during the time interval between the vapor-phase pulses of the reactant so as to form a gas phase barrier against the flow of the vaporized reactant from the reactant source via the first conduit into the reaction chamber. The inactive gas is withdrawn from said first conduit via a third conduit connected to the first conduit. A non-fully closing valve in the first conduit is placed into a reduced flow position when inactive gas is fed into said first conduit during the time interval between vapor-phase pulses of the reactant.

Another embodiment comprises an apparatus for growing a thin film onto a substrate according to the ALD method that includes: a reaction chamber; a reactant source in fluid communication with the reaction chamber via a first conduit; and an inactive gas source in fluid communication with the reaction chamber via a second conduit, wherein the second conduit is in fluid communication with the first conduit at a first connection point located upstream of the reaction chamber. A backsuction conduit is in fluid communication with the first conduit. The backsuction conduit is in fluid communication with the first conduit at a second connection point, and the second connection point is located upstream of the first connection point. A first non-fully closing valve is located along the backsuction conduit downstream of the second connection point. The first non-fully closing valve is switchable between a fully opened position and a fully closed position, and the first non-fully closing valve allows flow therethrough when in either position. A controller switches the first non-fully closing valve between the fully opened position and the fully closed position. The controller is configured to switch the first non-fully closing valve to the fully closed position to deliver reactant from the reactant source to the reaction chamber while the first non-fully closing valve remains in the closed position.

### BRIEF DESCRIPTION OF THE DRAWINGS

These and other aspects of the invention will be readily apparent from the following description and from the appended drawings (not to scale), which are meant to illustrate and not to limit the invention, and in which:

FIG. 1 is a schematic diagram of a system for processing films in accordance with an embodiment;

FIG. 2A is a schematic diagram of a portion of the system of FIG. 1 during a reactant pulse;

FIG. 2B is a schematic diagram of a portion of the system of FIG. 1 during a purge pulse;

FIG. 2C is a schematic diagram of a portion of the system of FIG. 1 during another embodiment of a reactant pulse;

FIG. 2D is a schematic diagram of a portion of the system of FIG. 1 during another embodiment of a reactant pulse; and

FIG. 3 is a schematic diagram of a flow regulation for processing films in accordance with an embodiment.

### DETAILED DESCRIPTION OF CERTAIN EMBODIMENTS

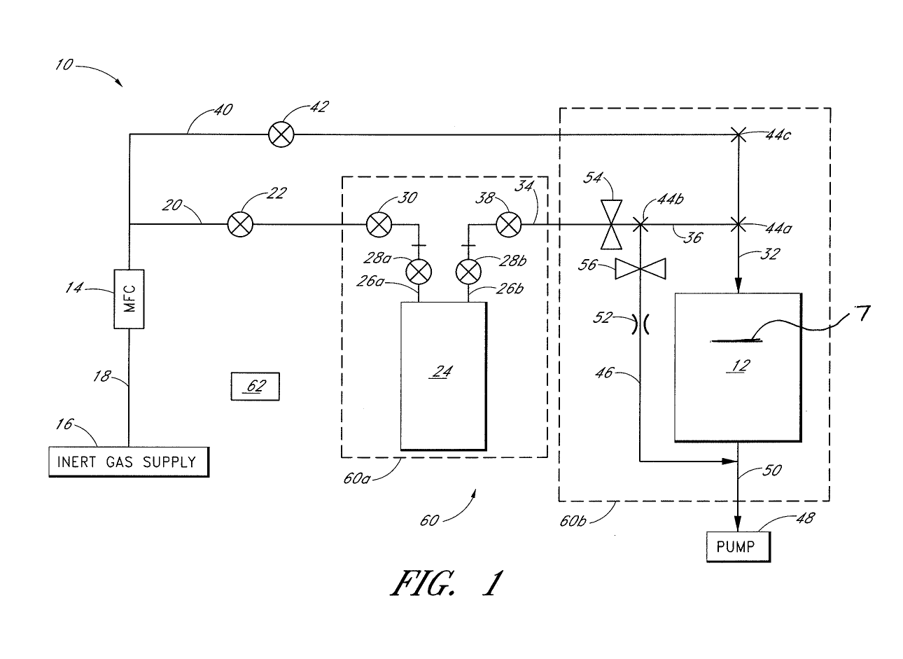

FIG. 1 is a schematic diagram of one embodiment of an apparatus 10 for growing a thin film onto a substrate 7 within a reaction chamber 12, using one or more reactants A, B, according to an ALD method. In the illustrated embodiment, a mass flow controller (MFC) 14 can receive an inert and/or inactive gas from an inert gas supply source 16. The inert gas can be introduced from the inert gas supply 16 into the mass flow controller 14 through an inert gas feed conduit 18.

The MFC 14 can be connected to a source feed conduit 20. A source feed valve 22 can be positioned within the source feed conduit 20. The source feed valve 22 can be configured to selectively allow and block flow through the source feed conduit 20 as described below. The source feed conduit 20 and the other conduits described herein can comprise many different materials and dimensions as is known in the art. For example, in some embodiments, the conduits can comprise pipes made from, e.g., metal or glass, as is known in the art. In other embodiments, the conduits can be formed from channels or recesses formed between one or more plates.

In the illustrated embodiment, the inactive gas is capable of preventing undesired reactions related to the reactants and the substrate, respectively. In the illustrated embodiment, the inactive gas can also be used as the carrier gas of the vapor-phase pulses of the reactants and, in particular, for providing a gas barrier to the flow of reactant residues into the reaction chamber during the purging of the reaction chamber, as described below. Inactive gases suited for use in the method are known in the art, and can include gasses such as nitrogen gas and the noble gases, e.g., argon.

In the illustrated embodiment, the source feed conduit 20 can extend between and can be in fluid communication with the MFC 14, the source feed valve 22 and a reactant source vessel 24 that can include a reactant or reactant precursor (also used herein as “Reactant A”). A second source feed valve 30 can be positioned within the source feed conduit 20 and can be used to selectively allow and block flow from the inert gas supply 16 into the reactant source vessel 24. The reactant source vessel 24 can comprise an inlet 26a for introduction of the inert gas into the reactant source vessel 24 from the inert gas supply 16 via the source feed conduit 20 and an outlet 26b which fluidly connects the reactant source vessel 24 to the reaction chamber 12 by way of a source conduit 35 for processing the substrate 7. A pair of isolation valves 28a, 28b can be provided adjacent to the inlet 26a and outlet 26b and can be used for assisting in replacing and/or removing the reactant source vessel 24 from the apparatus 10.

In an embodiment, the reactant source vessel 24 can be a container or similar vessel which is capable of containing the reactant material or precursor in solid or liquid form therein and in which the reactant material can be vaporized or evaporated to generate a vapor-phase reactant gas for delivery to the reaction chamber 12, as is known in the art. In another embodiment, the reactant source vessel 24 is a vessel that contains a reactant gas already in a vapor phase such that inert gas from the inert gas supply 16 may or may not be necessary to assist in transporting the reactant gas from the reactant source vessel 24 to the reaction chamber 12. In this alternative configuration (not shown), the reactant source vessel 24 may include only an outlet 26b without an inlet 26a or source feed conduit 20 for introducing inert gas from the inert gas supply 16 into the reactant source vessel 24. Although the embodiment illustrated in FIG. 1 shows a single reactant source vessel 24 operatively connected to the inert gas supply 16 and the reaction chamber 12, it should be understood by one skilled in the art that multiple reactant source vessels 24 can be operatively and selectively coupled to the source conduit 35.

In the embodiment illustrated in FIG. 1, the reactant source vessel 24 is located within an enclosure 60a. The enclosure 60a may include at least one heater (not shown) disposed therein. In the illustrated embodiment, a portion of the source feed conduit 20 operatively connected to the inlet 26a of the reactant source vessel 24 as well as a first source conduit section 34 operatively connected to the outlet 26b of the reactant source vessel 24 are located within the enclosure 60a. In the illustrated embodiment, the isolation valves 28a, 28b as well as the second source feed valve 30 and a source valve 38 are located within the enclosure 60a. However, it should be understood by one skilled in the art that any of the valves 28a, 28b, 30, 38 may be located outside the enclosure 60a. The heaters (not shown) located within the enclosure 60a are configured to provide heat and maintain the reactant source vessel 24, source feed conduit 20, first conduit section 34, and the valves 28a, 28b, 30, 38 at a temperature above the vaporization temperature of the reactant located within the reactant source vessel 24 to not only vaporize the reactant but assist in preventing condensation of the vapor-phase reactant within the first conduit section 34 or the valves 28b, 38 downstream of the reactant source vessel 24. In one embodiment, the isolation valves 28a, 28b are manually operated. In another embodiment, the isolation valves 28a, 28b can be operated through a controller (described below).

The outlet 26b of the reactant source vessel 24 can be interconnected and in fluid communication with an inlet 32 to the reaction chamber 12 via first and second source conduit sections 34, 36, which form a source conduit 35. While illustrated as separate sections, the first and second source conduit sections 34, 36 can comprise a single section of conduit or multiple sections. In the illustrated embodiment, the first and second source conduit sections 34, 36 can be in fluid communication with each other when a valve 54 (described below) is in an open position and can be connected in series as shown. In another embodiment (not shown), the first and second source conduit sections 34, 36 are in continuous fluid communication, wherein there is no valve 54 present along the source conduit 35. In the illustrated embodiment, the outlet 26b to the reactant source vessel 24 can be in fluid communication with a source valve 38, which can function similarly to the manner described above for the source feed valves 22, 30 to selectively allow and block flow of reactant gas and/or a reactant saturated carrier gas from the reactant source vessel 24 into reaction chamber 12.

As shown in FIG. 1, in the illustrated embodiment, the second source feed valve 30, the isolation valves 28a, 28b, the reactant source vessel 24 and the source valve 38 can be positioned within the enclosure 60a. As described below, the enclosure 60a can be provided with heating elements (not shown) and can be maintained at a reduced pressure. The heated valves within the enclosure 60a help ensure there are no cold spots that would otherwise cause condensation of the reactant within the vapor-phase reactant gas. The enclosure 60a can form a “reactant source delivery system”, which can form a modular unit for other reactants.

The reaction chamber 12 can comprise a chamber for processing a substrate positioned within, such as an ALD reaction chamber for growing thin films on a semiconductor wafer, as is known. An example of a commercially available ALD apparatus with a reaction chamber suitable for modifying to meet the description below is the P3000™, or PULSAR 3000™, supplied by ASM America, Inc. of Phoenix Ariz.

With continued reference to FIG. 1, the apparatus 10 can comprise a purge conduit 40 which is in fluid communication with the inert gas feed conduit 18 and the MFC 14. A purge valve 42 can be positioned within the purge conduit 40 to selectively allow and block flow of inert carrier gas.

The purge conduit 40 can extend between the MFC 14 and the reaction chamber 12 wherein the purge conduit 40 bypasses the reactant source vessel 24. The purge conduit 40 can comprise dimensions and materials, and function similarly to source feed conduit 20 described above. The purge conduit 40 and the MFC 14 can be configured to flow inactive gas into the reaction chamber 12 during a purging of the reaction chamber 12, described further below. Purging the reaction chamber comprises introducing inactive gas into the reaction chamber 12 between the vapor-phase pulses of the reactants. A purging process or sequence is carried out in order to reduce the concentration of the residues of the previous vapor-phase reactant pulse before the next vapor-phase reactant pulse is introduced and to prevent mixing of subsequent reactants.

The apparatus 10 can comprise a first connection point 44a that connects the source conduit 35 carrying reactant gas from the reactant source vessel 24 to the purge conduit 40 carrying inert gas that bypasses the solid source vessel 24. The first connection point 44a is located upstream relative to the reaction chamber 12 and downstream of the reactant source vessel 24. As will be described below, the first connection point 44a allows flow of inactive gas from the MFC 14 to form an inactive gas phase barrier with an inert gas valving (“IGV”) arrangement. The first connection point 44a can also be connected directly to the reaction chamber 12, or it can be in fluid communication with the reaction chamber 12 via the reaction chamber inlet 32 extending from first connection point 44a to the to reaction chamber 12.

The apparatus 10 can comprise a drain or backsuction conduit 46 that is in fluid communication with the first and second source conduit sections 34, 36 at a second connection point 44b. The second connection point 44b can connect the backsuction conduit 46 to the first and section source conduit sections 34, 36 between the connection point 44a and the reactant source vessel 24. As such, the second connection point 44b can be positioned upstream (with respect to the flow direction of the reactant gas from the reactant source vessel 24 or reactant source delivery system 60 to the reaction chamber 12 in a pulse step for reactant source A) of first connection point 44a and downstream of reactant source vessel 24. As such, the first connection point 44a can be positioned downstream from the second connection point 44b.

A pump 48 can be connected to the backsuction conduit 46. The backsuction conduit 46 can be connected to an outlet conduit 50 which is also connected and in fluid communication with reaction chamber 12. As such, the pump 48 can remove gas from backsuction conduit 46 and the reaction chamber 12. In some embodiments, backsuction conduit 46 can be connected to a separate outlet conduit and pump (not shown).

The backsuction conduit 46 can comprise one or more flow restrictions, such as a capillary 52, which can be used to reduce the cross-section of the backsuction conduit 46 and restrict the flow therethrough. The capillary 52 can be removable so that it can be replaced, or exchanged for a capillary of different characteristics, such as a capillary with a different cross section or temperature resistance. The capillary 52 can comprise a durable material, and/or may comprise no moving parts. The backsuction conduit 46, which bypasses the reaction chamber 12, drains the first and second source conduit sections 34, 36, as described further below. In order to avoid condensation, the backsuction conduit 46 can be maintained at a temperature equal to or higher than the condensation of the vapor-phase reactant. In another embodiment, the temperature can be equal to or lower than the reaction temperature. In an embodiment, one or more valves can be configured in the backsuction conduit 46 as described further below. The backsuction conduit 46 can comprise materials and dimensions similar to the conduits described above.

The apparatus 10 can further comprise a non-fully closing or leaky source valve 54 to regulate the flow of gas through the first and second source conduit sections 34, 36. The non-fully closing source valve 54 can be positioned between the reactant source vessel 24 and the second connection point 44b. The leaky source valve 54 can be switchable between operable positions including: a fully opened position, a fully closed position, or a choked position that is between the fully opened and fully closed positions. In the fully closed position, the leaky source valve 54 still allows at least some flow of gases therethrough. In one embodiment, when the leaky source valve 54 is in the fully closed position, the leaky source valve 54 has a helium leak rate that is greater than 4×10⁻⁹ std cc/sec but less than the flow rate through the leaky source valve 54 in the fully opened position. In another embodiment, the flow through the leaky source valve 54 when in the fully closed position can range from about zero to about 1/10 of the flow through the source leaky valve 54 when it is in the fully opened position. A non-limiting example of the flow coefficient (Cv) range for a ¼″ technology valve in an open position can be equal to or between about 0.05 to about 0.5 and in a closed position the Cv can be less than or equal to about 0.005 and in another embodiment less than or equal to about 0.0000005 and in still another embodiment the Cv would be about zero. In another embodiment, the leaky source valve 54 can have a leak rate that is greater than zero in the fully closed position but less than 10 sccm (standard cubic centimeters per minute), and in another embodiment, less than 1 sccm, in another embodiment 0.1 sccm and in another embodiment, less than 0.005 sccm.

In another embodiment, the flow through the leaky source valve 54 in the fully closed position is less than or equal to about 1% of the flow that the leaky source valve 54 when the valve is in the fully opened position. In another embodiment, the flow allowed by the leaky source valve 54 when in the choked position is less than or equal to about 10% of the flow it allows in its fully opened position. In an embodiment, the response time of the leaky source valve 54 to switch from one position (fully open or fully closed) to another is less than 100 ms, in a preferred embodiment, it is less than 10 ms. In one embodiment, the source valve 54 has a high cycle life (e.g., greater than 1 million cycles) and can withstand high temperature environments (e.g., greater than 400 Celsius and more preferably greater than 600 Celsius).

The apparatus 10 can further comprise a backsuction leaky valve 56. The backsuction leaky valve 56 can have similar characteristics to the leaky source valve 54 described above. The backsuction leaky valve 56 can be positioned in the backsuction conduit 46, downstream of the second connection point 44b. As described above, the backsuction conduit 46 can include a hot drain capillary 52 which restricts the flow of gas through backsuction conduit 46 In an embodiment comprising a hot drain capillary 52, the backsuction leaky valve 56 can be located upstream of the hot drain capillary 52 or downstream of the hot drain capillary 52 (in a modified embodiment). In another embodiment, the hot drain capillary 52 can be eliminated.

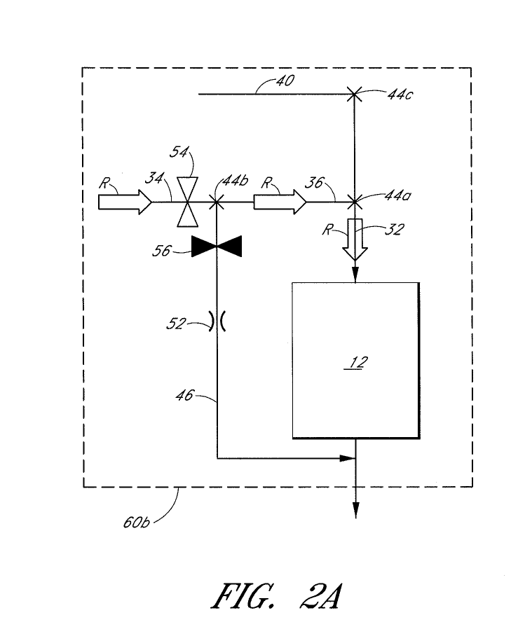

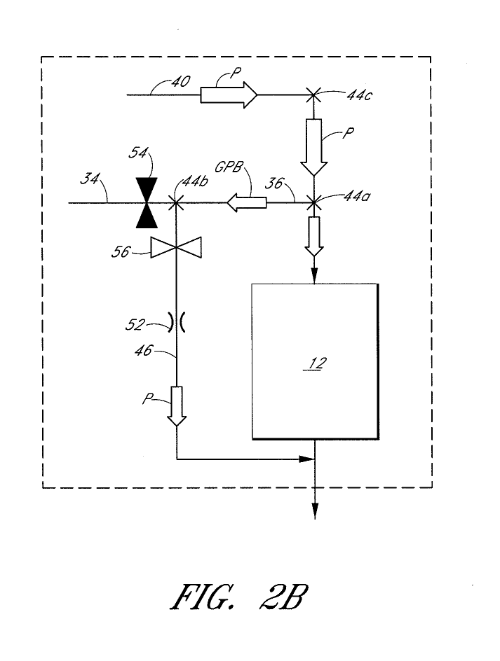

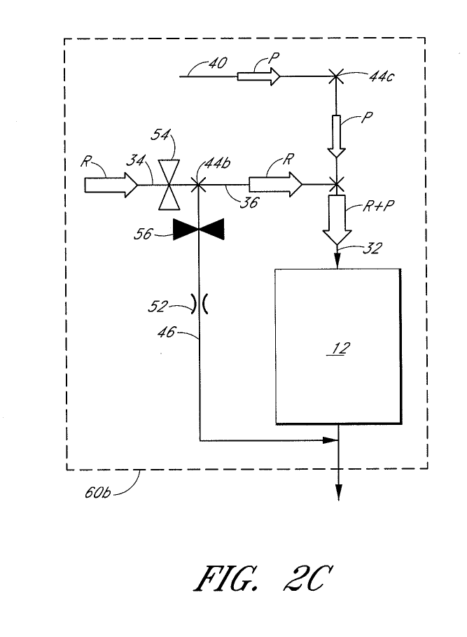

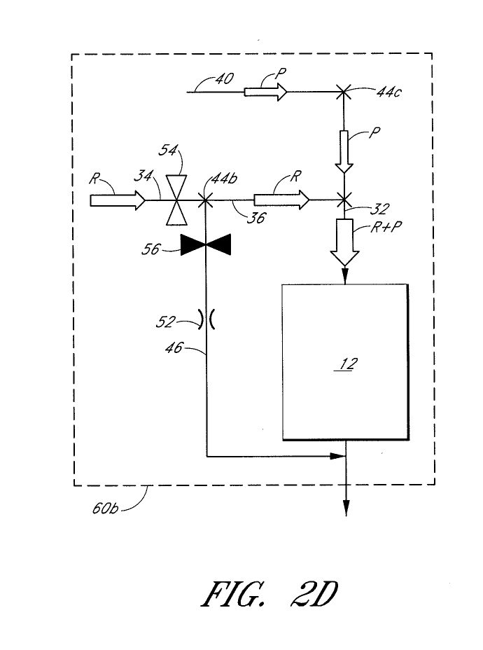

With reference to FIGS. 1 and 2A, in one embodiment, during a reactant pulse step, the inactive gas can be used as a carrier gas, which flows from the inert gas supply 18, through source feed conduit 20, through source feed valves 22, 30 and the isolation valve 28a (which are in a position to allow flow therethrough), and through the reactant source vessel 24 to form a reactant gas and/or a reactant saturated carrier gas R. The reactant gas subsequently can flow from the reactant source vessel 24 through the isolation valve 28b and source valve 38 and source conduit sections 34 and 36 to the reaction inlet 32 and into the reaction chamber 12. In the embodiment, illustrated in FIG. 2A, the purge valve 42 (not shown in FIG. 2A) can be closed so that no or substantially no inert gas flows though the purge conduit 40. In addition, in the illustrated embodiment, the backsuction leaky valve 56 is illustrated as being in a fully closed position to reduce or eliminate reactant R flow into the backsuction conduit 46. In some embodiments, the apparatus 10 can comprise a second, third or more reactant sources that can provide other source for a reactant pulse. The pulse of the additional reactant(s) can be provided from another flow system and can be connected to the illustrated apparatus at connection potions 44c and/or 44a respectively. The additional reactant systems can comprise similar valving and conduit structures as described herein.

The reactant R carried in the source conduit sections 34 and 36 can be any material capable of reacting with the substrate surface, and the reactant R may or may not include the carrier gas. In other words, FIG. 1A illustrates a reactant source vessel 24, but it should be understood by one skilled in the art that a reactant R may be introduced directly into the source conduit section 34 without requiring an inert gas supply and a reactant source vessel 24. In the ALD method, vaporizable reactants belonging to two different groups are conventionally employed. The reactants can be solids, liquids or gases. Metallic reactants are typically metallic compounds which can comprise elemental metals. Suitable metallic reactants are the halogenides of metals including chlorides and bromides, for instance, and organometallic compounds such as the the complex compounds. As examples of metallic reactants can be mentioned HfCl4, ZrCl4, ZnI₂, TiCl₄, La(the)₃, TEMAH (Hf[N(C₂H₅)(CH₃)]₄), (CH₃)₃Al, and MgCp₂. Nonmetallic reactants are typically compounds and elements capable of reacting with metallic compounds. Nonmetallic reactants may include water, ozone, hydrogen, hydrogen sulfide and ammonia.

With reference to FIG. 2B, an inert gas valving (“IGV”) arrangement can be used such that second source conduit section 36 comprises an inactive gas phase barrier (GPB). An IGV arrangement can be useful during a purge step or during the pulse of a second reactant B. The gas phase barrier can prevent the flow of reactant gas from the reactant source vessel 24 into the reaction chamber 12. The gas phase barrier GPB generally comprises a flow of inactive gas P which is flowed from MFC 14 through the purge valve 42 (FIG. 1A) through the purge conduit 40 and into the second source conduit section 36 via the first connection point 44a. Subsequently, the inactive gas P can be withdrawn from the source conduit section 36 through the second connection point 44b via the backsuction conduit 46. In this illustrated arrangement, the leaky source valve 54 by itself (or in modified embodiments along with 38, 30 and 22) can be closed and backsuction leaky valve 56 is in a fully opened position to divert the all of the inactive gas P from the MFC 14 into the first connection point 44a and prevent further reactant flow into the second connection point 44b from upstream. This arrangement maximizes the flow through backsuction conduit 46, which increases the GPB flowrate against a quickly decreasing flow of precursor. As shown in FIG. 2B, a portion of the inactive gas P can also be directed through the reaction chamber inlet 32 and into the reaction chamber 12 for purging the reaction chamber 12. The flow rate of the inactive gas P into the reaction inlet 32 versus the flow rate into the source conduit section 36 is determined by relative resistance in the two flow paths originating at the first connection point 44a. As shown in FIG. 2B, during the purge step or during the reactant pulse of reactant B, the inactive gas that forms gas phase barrier GPB flows in the second source conduit section 36 in a direction opposite to the flow of the reactant in the second source conduit section 36 during the reactant pulse step described above. Thus, for some length of the second source conduit section 36, the inactive gas fed via the purge conduit 40 can be conducted in a direction opposite to the reactant flow. Any reactant R remaining in the second source conduit section 36 downstream of the leaky source valve 54 after the reactant pulse step may be diverted into the backsuction conduit 46 along with the inactive gas P. As such, the barrier zone GPB (which comprises the length of the second source conduit section 36 between the first and second connection points 44a, 44b) exhibits a gas flow pattern which is generally directed toward the reactor during pulsing and toward the reactant source during an inert gas valving (“IGV”) cycle. During a pulse step, the pump can also draw a portion of the vapor-phase reactants R away from the reaction chamber 12 via an outlet conduit 50 connected to a pump 48.

In an embodiment, the reactant vapor residues withdrawn via the backsuction conduit 46 can be recirculated and reused via a recirculation conduit (not shown). However, the reactant can also be discarded. According to a modified arrangement, the backsuction conduit 46 can be connected to a condensation vessel (not shown) maintained at a lower pressure and/or temperature in order to provide condensation of vaporized reactant residues.

During a purge, the flow of gas through the backsuction conduit 46 is greater than the flow of gas through the source conduit 20 to ensure that reactant R from the reactant source vessel 24 is not introduced into the reaction chamber 12. However, it can be advantageous, during a reactant pulse, for the flow of gas through the backsuction conduit 46 to be less than the flow of gas through the source conduit 20 to reduce waste. In one embodiment, the flow through the backsuction conduit 46 is about one fifth of that in the source conduit 20. Preferably, it is less than 15%, and more preferably 10% or less of the flow via the source conduit 20 into the reaction chamber 12.

As illustrated in FIG. 1A, the non-fully closed valves 54, 56, valves 30, 28a, 28b, 38, reactant source vessel 24, reaction chamber 12, backsuction conduit 46, capillary 52, connection points 44a, 44b, 44c, and the conduit sections therebetween can be positioned within a hot zone 60. Hot zone 60 can comprise the source heated zone 60a and a reactor heated zone 60b. As mentioned above, the source 24 and associated valves 30, 28a, 28b, 28 can be positioned within the source heated zone 60a which can comprise an enclosure that can be held at a reduced pressure and is sometimes referred to a reactant source delivery system. The enclosure (not shown) can include one ore more heaters (e.g., radiant heaters and/or resistance heaters) to maintain the components positioned within the enclosure at the desired temperature. The valves 54, 56 and the reaction chamber 12, backsuction conduit 46, capillary 52, connection points 44a, 44b, 44c, and conduit sections therebetween can be positioned within the reactor heated zone 60b. The first source conduit section 34 can be positioned in either source heated zone 60a, reactor heated zone 60b, or both. MFC 14, and valves 22, 42 can be positioned outside of hot zone 60 as illustrated, although one or more of these components can be positioned within hot zone 60 in modified embodiments. In an embodiment, the hot zone can comprise a zone within which the temperature is the same as the evaporation temperature of the reactants or higher. Depending on the reactants, typically the temperature within the source heated zone 60a [is in the range of 25 to 500° C., in particular about 50 to 250° C. The reactor heated zone 60b can be in the range of about 100-=to about 400° C. The pressure in the reaction chamber 12 and in the gas flow channels freely communicating with the reaction chamber 12 can be atmospheric but it is preferred to operate at reduced pressure, in particular at a pressure in the range of 1 to 100 mbar. It is understood by a skilled artisan that in modified embodiments additional valves and components (e.g., filters, purifiers, gas flow regulators, etc.) can be positioned along the conduits described above. In addition, those of skilled in the art will recognize in light of the disclosure herein that not all of the valve and components shown in the illustrated embodiment are required for performing the functions and steps described herein.

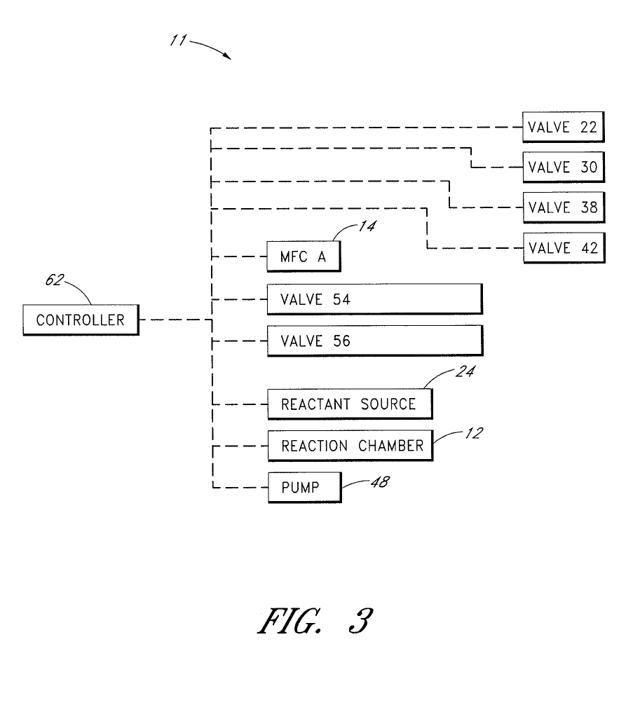

FIG. 3 is schematic diagram of a flow regulation system 11 that illustrates the relationship between a controller 62 and the various valves and components of the system 10. The controller 62 can be operatively coupled to the leaky valves 54, 56, and the other components of system 10 described above, such as MFC 14, the pump 48, the reactant source vessel 24, the valves 22, 30, 38 and 42. The valves can comprise solenoid or electrically-operated valves that are controlled by the controller 12, but are, in one embodiment, pneumatically actuated valves with pneumatic air delivered by a valve terminal block which can comprise a manifold of solenoid valves to actuate pneumatic air. As such, the controller 62 can control to open and close sequentially, or simultaneously, during the ALD process.

The controller 62 can be in many forms as is known to those of skill in the art. For example, the controller 62 can comprise a computer control system. The control system can include modules such as a software and/or a hardware component, such as a FPGA or ASIC, which performs certain tasks. A module may advantageously be configured to reside on the addressable storage medium of the computer control system and be configured to execute on one or more processors.

With the apparatus described above, various types of reactant pulses can be generated. For example, in one type of reactant pulse shown in FIG. 2C, the purge valve 42 in the purge conduit 40 and the valves 22, 30, 28a, 28b, 38 in the source feed conduit 20 and source conduit 34 are all open. The resistance through the purge conduit 40 and the source conduits 20, 34, 36 can be configured such that the reactant gas R from the source conduits 20, 34, 36 and the inactive gas P in the purge conduit 40 can be combined (R+P) in the reaction chamber inlet 32 during a reactant pulse. In this pulse, the leaky source valve 54 can be in an open position while the backsuction leaky valve 56 in the backsuction conduit 46 is in a closed position. This configuration reduces reaction gas losses through the backsuction conduit 46 during a reactant pulse.

In another embodiment of a reactant pulse shown in FIG. 2A (also described above), the purge valve 42 in the purge conduit 40 is closed while the valves 22, 30, 28a, 28b, 38 in the source feed conduit 20 and source conduit 35 are all open. In this position, all of the carrier gas flow towards the reactant source vessel 24. In this pulse, the leaky source valve 54 can be in an open position while the backsuction leaky valve 56 in the backsuction conduit 46 is in a closed position. This configuration also reduces reaction gas R losses through the backsuction conduit 46 during a reactant pulse.

In another type of reactant pulse shown in FIG. 2D, the purge valve 42 in the purge conduit 40 can be either in an open or closed position (in the illustrated embodiment of FIG. 2D the purge conduit 40 is open). The valves 28b, 38 in the source conduit 34 are all open while the valves 22, 30, 28a are closed. In this manner, a vapor draw from the reactant source vessel 24 can be accomplished. In this pulse, the leaky source valve 54 can be in an open position while the backsuction leaky valve 56 in the backsuction conduit 46 is in a closed position. This configuration also reduces reaction gas losses through the backsuction conduit 46 during a reactant pulse.

During a purge cycle for the embodiments described above and shown in FIG. 2B, the leaky source valve 54 can be closed and the backsuction leaky valve 56 can be opened with the flow through the backsuction conduit 46 being defined, in part, by the restriction 52. The gas phase barrier created by the flow of inert gas P from the first connection point 44a through the second source conduit 36 prevents any reactant gas flowing through the leaky source valve 54 from entering the reaction chamber 12. Instead, the reactant gas leaking through the leaky source valve 54 during the purge cycle is directed through the backsuction conduit 46 at the second connection point 44b. In a modified arrangement, the restriction 52 can be eliminated.

With reference back to FIG. 1, in one embodiment, the leaky backsuction valve 56 can be eliminated from the backsuction conduit. In one arrangement, during a purge cycle the leaky source valve 54 can be closed, and the flow of purge gas through backsuction conduit 46 is dictated by the orifice 52. During a pulse cycle of such an embodiment, the leaky source valve 54 can be open, and the waste of reactant through backsuction conduit 46 is dictated by the orifice 52.

In another arrangement, the source leaky valve 54 can be eliminated. In one arrangement, during a purge cycle, the leaky backsuction valve 56 can be open, allowing flow of purge gas through backsuction conduit 46 as described above. This prevents the flow of reactant trapped between connection 44b and the source valve 38 toward reactor 12 and/or into backsuction conduit 46. During a pulse cycle, the leaky backsuction valve 56 can be closed, reducing the amount of reactant wasted through backsuction conduit 46.

Although this invention has been disclosed in the context of certain embodiments and examples, it will be understood by those skilled in the art that the present invention extends beyond the specifically disclosed embodiments to other alternative embodiments and/or uses of the invention and obvious modifications thereof. Thus, it is intended that the scope of the present invention herein disclosed should not be limited by the particular disclosed embodiments described above, but should be determined only by a fair reading of the claims that follow.

What is claimed is:

1. An apparatus for growing a thin film onto a substrate according to the ALD method, the apparatus comprising:
a reaction chamber;
a reactant source in fluid communication with the reaction chamber via a first conduit;
an inactive gas source in fluid communication with the reaction chamber via a second conduit, wherein the second conduit is in fluid communication with the first conduit at a first connection point located upstream of the reaction chamber;
a backsuction conduit in fluid communication with the first conduit, wherein the backsuction conduit is in fluid communication with the first conduit at a second connection point, and the second connection point is located upstream of the first connection point;
a first non-fully closing valve located along the backsuction conduit downstream of the second connection point, wherein the first non-fully closing valve is switchable between a fully opened position and a fully closed position, and the first non-fully closing valve allows flow therethrough when in either position; and
a controller for switching the first non-fully closing valve between the fully opened position and the fully closed position, wherein the controller is configured to switch the first non-fully closing valve to the fully closed position to deliver reactant from the reactant source to the reaction chamber while the first non-fully closing valve remains in the closed position.

2. The apparatus according to claim 1, wherein the first non-fully closing valve in the fully closed position has a flow therethrough that is less than or equal to about 1/10 of the flow when the first non-fully closing valve is in the fully opened position.

3. The apparatus according to claim 1, wherein the first non-fully closing valve has a response time for switching between the fully opened and fully closed positions that is less than about 100 ms.

4. The apparatus according to claim 1, wherein the first non-fully closing valve in the fully closed position has a helium leak rate that is greater than 4×10⁻⁹ std. cc/sec.

5. The apparatus according to claim 1, wherein the first non-fully closing valve in the fully closed position has a leak rate that is greater than zero but less than or equal to about 10 sccm.

6. The apparatus according to claim 1, wherein the first non-fully closing valve in the fully opened position has a flow coefficient of about 0.05 to 0.5 and in the fully closed position has a leak rate with a flow coefficient equal to or less than 0.005.

7. The apparatus according to claim 1, wherein the first non-fully closing valve in the fully closed position has a leak rate that is greater than zero but less than or equal to about 10% of the flow rate when in the fully opened position.

8. The apparatus according to claim 1 further comprising a mass flow controller configured to regulate the inactive gas flow through the second conduit.

9. The apparatus according to claim 1, further comprising a second non-fully closing valve that is located upstream of the second connection point, wherein the second non-fully closing valve is switchable between a fully opened position and a fully closed position, and gas flows through the second non-fully closing valve when in either position.

10. The apparatus according to claim 9, wherein the second non-fully closing valve is in the fully opened position when the first non-fully closing valve is in the fully closed position for delivering reactant to the reaction chamber.

11. The apparatus according to claim 10, wherein the controller switches the first non-fully closing valve to the fully opened position and the second non-fully closing valve to the fully closed position for delivering inactive gas to the reaction chamber, thereby creating a gas phase barrier in the first conduit.

12. The apparatus according to claim 11, wherein the gas phase barrier causes all of the reactant flowing through the second non-fully closing valve when the second non-fully closing valve is in the fully closed position and the first non-fully closing valve is in the fully opened position into the backsuction conduit without being introduced into the reaction chamber.

13. The apparatus according to claim 1, wherein the inactive gas source is in fluid communication with the reactant source for providing inactive gas to the reactant source via a third conduit.

14. A method of growing a thin film onto a substrate placed in a reaction chamber according to the ALD method, said method comprising the steps of:
vaporizing a reactant from a reactant source maintained at a vaporizing temperature;
conducting the vaporized reactant to the reaction chamber via a first conduit;
feeding the reactant into said reaction chamber though the first conduct in the form of vapor-phase pulses repeatedly and alternately with vapor-phase pulses of at least one other reactant;
causing said vapor-phase reactant to react with the surface of the substrate at a reaction temperature to form a thin film compound on said substrate;
feeding inactive gas into said first conduit via a second conduit, connected to the first conduit at a first connection point, during the time interval between the vapor-phase pulses of the reactant so as to form a gas phase barrier against the flow of the vaporized reactant from the reactant source via the first conduit into the reaction chamber;
withdrawing the inactive gas from said first conduit via a third conduit connected to the first conduit and through a non-fully closing valve in an open position in the third conduit; and
placing the non-fully closing valve in the third conduit into a reduced flow position when feeding the reactant into said chamber through the first conduit.

15. The method according to claim 14, wherein the non-fully closing valve in the in the closed position has flow that is less than or equal to about 1/10 of the flow of the open position of the non-fully closing valve.

16. The method according to claim 14, wherein the non-fully closing valve has an open position and a closed position with a helium leak rate that is greater than or equal to about 4×10⁻⁹ std. cc/sec.

17. The method according to claim 14, wherein the non-fully closing valve has an open position and a closed position with a leak rate that is greater than zero but less or equal to about 10 sccm.

18. The method according to claim 14, wherein the first non-fully closing valve in the open position has a flow coefficient of about 0.05 to 0.5 and in the reduced flow position has a leak rate with a flow coefficient equal to or less than 0.005.

19. The method according to claim 14, wherein feeding the inactive gas into the first conduit comprises feeding the inactive gas into the first conduit at a point downstream from the connection point at which the second conduit is connected to the first conduit to provide a flow of inactive gas which is directed in the opposite direction to the reactant flow in the first conduit.

20. The method according to claim 14, comprising feeding inactive gas into the third conduit through a fourth conduit.

21. The method according to claim 20, wherein inactive gas is fed into the reaction chamber between the vapor-phase pulses of said reactants.

22. A method of growing a thin film onto a substrate placed in a reaction chamber according to the ALD method, said method comprising the steps of:
vaporizing a reactant from a reactant source maintained at a vaporizing temperature;
conducting the vaporized reactant to the reaction chamber via a first conduit;
feeding the reactant into said reaction chamber though the first conduct in the form of vapor-phase pulses repeatedly and alternately with vapor-phase pulses of at least one other reactant;
causing said vapor-phase reactant to react with the surface of the substrate at a reaction temperature to form a thin film compound on said substrate;
feeding inactive gas into said first conduit via a second conduit, connected to the first conduit at a first connection point, during the time interval between the vapor-phase pulses of the reactant so as to form a gas phase barrier against the flow of the vaporized reactant from the reactant source via the first conduit into the reaction chamber;
withdrawing the inactive gas from said first conduit via a third conduit connected to the first conduit; and
placing a non-fully closing valve in the first conduit into a reduced flow position when inactive gas is fed into said first conduit during the time interval between vapor-phase pulses of the reactant.

23. An apparatus for growing a thin film onto a substrate according to the ALD method, the apparatus comprising:
a reaction chamber in which the substrate is positioned;
a reactant source in communication with the reaction chamber for providing a reactant via a first conduit; and
a flow regulation system configured to regulate the flow of reactant via the first conduit into said reaction chamber to cause the reactant to enter the reaction chamber in the form of repeated reactant vapor-phase pulses that alternate with purge steps and repeated vapor-phase pulses of at least one other reactant to react with a surface of the substrate at a reaction temperature to form a thin film on said substrate;
wherein the flow regulation system comprises:
a source of inactive gas, which is in communication with the first conduit via a second conduit which is connected to the first conduit at a first connection point;
a backsuction conduit, which is in communication with the first conduit via a third conduit which is connected to the first conduit at a second connection point upstream of the first connection point; and
a first non-fully closing valve, which is located downstream of the second connection point, wherein the first non-fully closing valve provides flow therethrough when in a closed position, the first non-fully closing valve in an the closed position during a reactant vapor-phase pulse and in an open position during a purge step.
